(19) United States
(12) Patent Application Publication
(10) Pub. No.: US 2024/0315035 A1
(43) Pub. Date: Sep. 19, 2024

(54) Memory Arrays Comprising Strings Of Memory Cells And Methods Used In Forming A Memory Array Comprising Strings Of Memory Cells

(71) Applicant: Micron Technology, Inc., Boise, ID (US)

(72) Inventor: James Lattin, Boise, ID (US)

(73) Assignee: Micron Technology, Inc., Boise, ID (US)

(21) Appl. No.: 18/582,291

(22) Filed: Feb. 20, 2024

Related U.S. Application Data
(60) Provisional application No. 63/452,762, filed on Mar. 17, 2023.

(51) Int. Cl. H10B 43/35; H10B 41/27; H10B 41/35; H10B 43/27

(52) U.S. Cl. CPC H10B 43/35; H10B 41/27; H10B 41/35; H10B 43/27

(57) ABSTRACT

A method used in forming a memory array comprising strings of memory cells comprises forming a stack comprising vertically-alternating insulative tiers and conductive tiers. The stack comprises laterally-spaced memory blocks an upper portion of which individually comprise sub-blocks. The conductive tiers of the sub-blocks individually comprise select-gate tiers that individually comprise select gates. Sub-block trenches are in the upper portion of the memory blocks and are individually between immediately-laterally-adjacent of the sub-blocks. The sub-block trenches individually extend through and horizontally-along the select-gate tiers and the insulative tiers of the sub-blocks. In the sub-block trenches, conducting material of the select-gate tiers is recessed laterally-outward relative to sub-block trench sidewalls of insulative material of the insulative tiers of the sub-blocks to form lateral recesses in the select-gate tiers. Insulating material is formed in the sub-block trenches and in the lateral recesses. Other aspects, including structure independent of method, are disclosed.

### TECHNICAL FIELD

Embodiments disclosed herein pertain to memory arrays comprising strings of memory cells and to methods used in forming a memory array comprising strings of memory cells.

### BACKGROUND

Memory is one type of integrated circuitry and is used in computer systems for storing data. Memory may be fabricated in one or more arrays of individual memory cells. Memory cells may be written to, or read from, using digitlines (which may also be referred to as bitlines, data lines, or sense lines) and access lines (which may also be referred to as wordlines). The sense lines may conductively interconnect memory cells along columns of the array, and the access lines may conductively interconnect memory cells along rows of the array. Each memory cell may be uniquely addressed through the combination of a sense line and an access line.

Memory cells may be volatile, semi-volatile, or non-volatile. Non-volatile memory cells can store data for extended periods of time in the absence of power. Non-volatile memory is conventionally specified to be memory having a retention time of at least about 10 years. Volatile memory dissipates and is therefore refreshed/rewritten to maintain data storage. Volatile memory may have a retention time of milliseconds or less. Regardless, memory cells are configured to retain or store memory in at least two different selectable states. In a binary system, the states are considered as either a “0” or a “1”. In other systems, at least some individual memory cells may be configured to store more than two levels or states of information.

A field effect transistor is one type of electronic component that may be used in a memory cell. These transistors comprise a pair of conductive source/drain regions having a semiconductive channel region there-between. A conductive gate is adjacent the channel region and separated there-from by a thin gate insulator. Application of a suitable voltage to the gate allows current to flow from one of the source/drain regions to the other through the channel region. When the voltage is removed from the gate, current is largely prevented from flowing through the channel region. Field effect transistors may also include additional structure, for example a reversibly programmable charge-storage region as part of the gate construction between the gate insulator and the conductive gate.

NAND may be a basic architecture of integrated flash memory. A NAND cell unit comprises at least one selecting device coupled in series to a serial combination of memory cells (with the serial combination commonly being referred to as a NAND string). NAND architecture may be configured in a three-dimensional arrangement comprising vertically-stacked memory cells individually comprising a reversibly programmable vertical transistor. Control or other circuitry may be formed below the vertically-stacked memory cells. Other volatile or non-volatile memory array architectures may also comprise vertically-stacked memory cells that individually comprise a transistor.

Memory arrays may be arranged in memory pages, memory blocks and partial blocks (e.g., sub-blocks), and memory planes, for example as shown and described in any of U.S. Patent Application Publication Nos. 2015/0228651, 2016/0267984, and 2017/0140833. The memory blocks may at least in part define longitudinal outlines of individual wordlines in individual wordline tiers of vertically-stacked memory cells. Connections to these wordlines may occur in a so-called “stair-step structure” at an end or edge of an array of the vertically-stacked memory cells. The stair-step structure includes individual “stairs” (alternately termed “steps” or “stair-steps”) that define contact regions of the individual wordlines upon which elevationally-extending conductive vias contact to provide electrical access to the wordlines.

### BRIEF DESCRIPTION OF THE DRAWINGS

FIG. 1 is a diagrammatic cross-sectional view of a portion of a substrate in process in accordance with an embodiment of the invention.

FIGS. 2-19 are diagrammatic sequential sectional and/or enlarged views of the construction of FIG. 1 and/or alternate embodiments in process in accordance with some embodiments of the invention.

### DETAILED DESCRIPTION OF EXAMPLE EMBODIMENTS

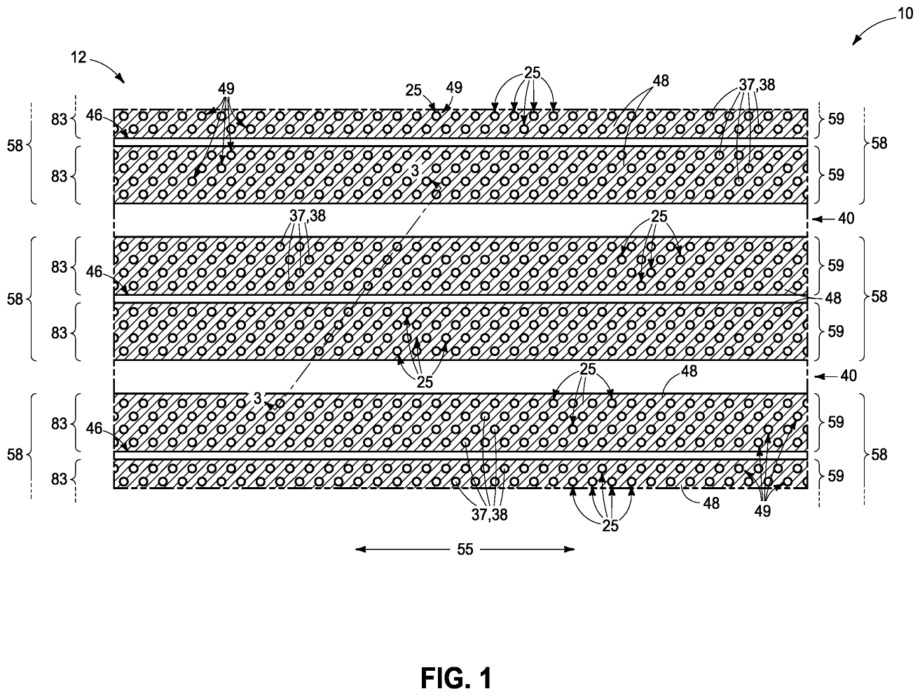

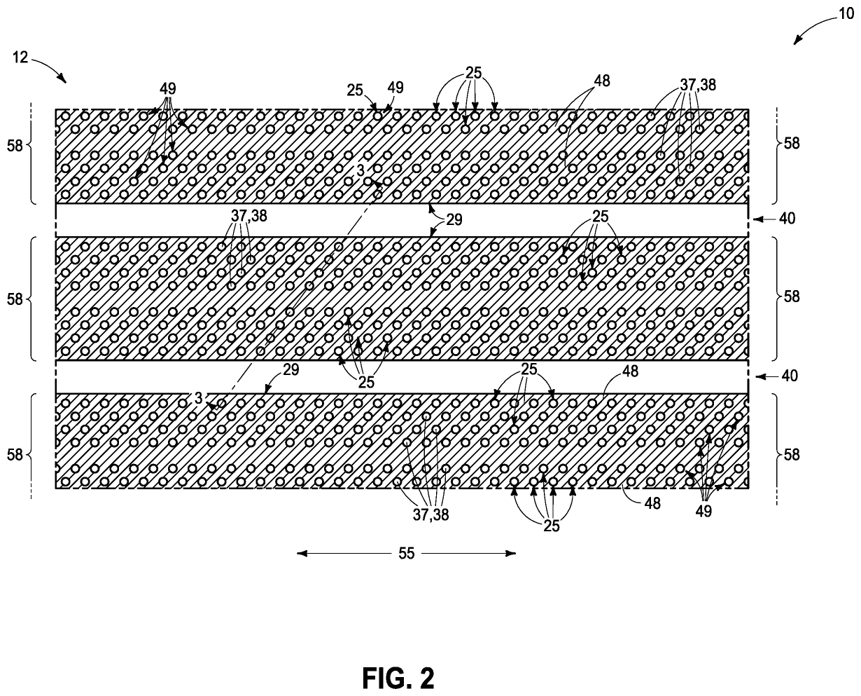

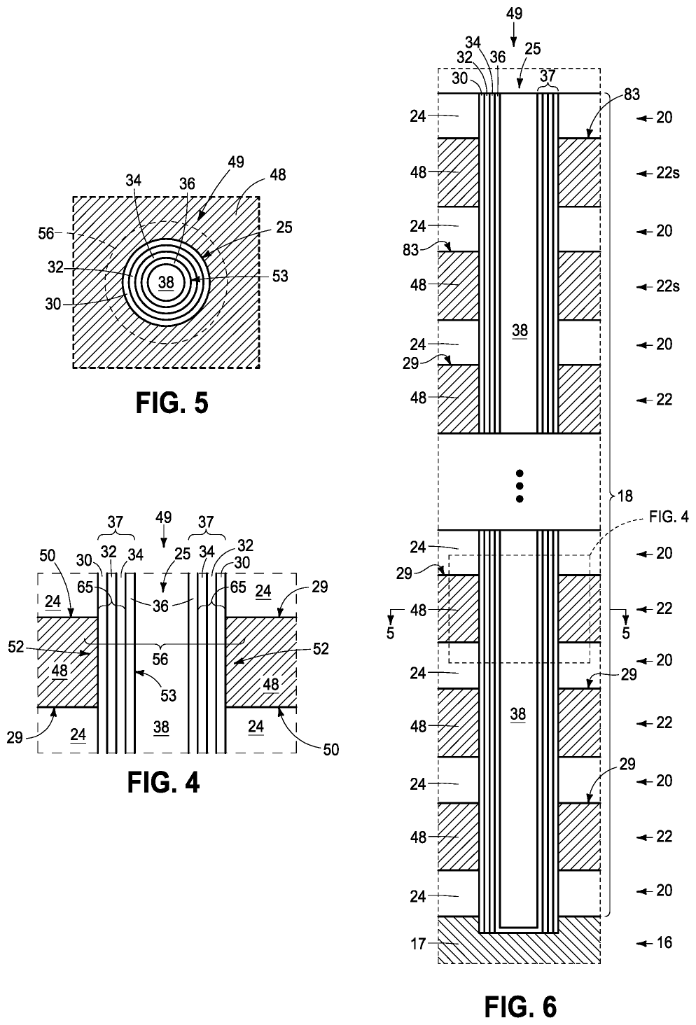

Embodiments of the invention encompass methods used in forming a memory array, for example an array of NAND or other memory cells that may have at least some peripheral control circuitry under the array (e.g., CMOS-under-array). Embodiments of the invention encompass so-called “gate-last” or “replacement-gate” processing, so-called “gate-first” processing, and other processing whether existing or future-developed independent of when transistor gates are formed. Embodiments of the invention also encompass a memory array (e.g., NAND architecture) independent of method of manufacture. First example method embodiments are described with reference to FIGS. 1-19.

FIGS. 1-6 show but one example construction 10 having an array or array area 12 in which elevationally-extending strings 49 of transistors and/or memory cells 56 have been formed. Example construction 10 includes a base substrate 11 having any one or more of conductive/conductor/conducting, semiconductive/semiconductor/semiconducting, or insulative/insulator/insulating (i.e., electrically herein) materials. Various materials have been formed elevationally over base substrate 11. Materials may be aside, elevationally inward, or elevationally outward of the FIGS. 1-6-depicted materials. For example, other partially or wholly fabricated components of integrated circuitry may be provided somewhere above, about, or within base substrate 11. Control and/or other peripheral circuitry for operating components within an array (e.g., array 12) of elevationally-extending strings of memory cells may also be fabricated and may or may not be wholly or partially within an array or sub-array. Further, multiple sub-arrays may also be fabricated and operated independently, in tandem, or otherwise relative one another. In this document, a “sub-array” may also be considered as an array.

A conductor tier 16 comprising conductor material 17 (e.g., conductively-doped polysilicon atop WSiₓ) has been formed above substrate 11. Conductor tier 16 may comprise part of control circuitry (e.g., peripheral-under-array circuitry and/or a common source line or plate) used to control read and write access to the transistors and/or memory cells that will be formed within array 12. A stack 18 comprising vertically-alternating insulative tiers 20 and conductive tiers 22* has been formed above conductor tier 16 (an * being used as a suffix to be inclusive of all such same-numerically-designated components that may or may not have other suffixes). Example thickness for each of tiers 20 and 22* is 20 to 60 nanometers. The example uppermost tier 20 may be thicker/thickest compared to one or more other tiers 20 and/or 22*. Only a small number of tiers 20 and 22* is shown, with more likely stack 18 comprising dozens, a hundred or more, etc. of tiers 20 and 22*. Other circuitry that may or may not be part of peripheral and/or control circuitry may be between conductor tier 16 and stack 18. For example, multiple vertically-alternating tiers of conductive material and insulative material of such circuitry may be below a lowest of the conductive tiers 22* and/or above an uppermost of the conductive tiers 22*. For example, one or more select gate tiers (not shown) may be between conductor tier 16 and the lowest conductive tier 22*. Example insulative tiers 20 comprise insulative material 24 (e.g., silicon dioxide and/or other material that may be of one or more composition(s)).

Stack 18 comprises laterally-spaced memory blocks 58, with an upper portion of individual memory blocks 58 (e.g., the uppermost portion thereof) comprising sub-blocks 59. Only two sub-blocks 59 are shown in each memory block 58 although more sub-blocks may be in each and not all memory blocks need have the same number of sub-blocks. Memory blocks 58 and sub-blocks 59 may be considered as being longitudinally elongated and oriented, for example along a direction 55. Conductive tiers 22* of sub-blocks 59 individually comprise select-gate tiers 22s. Sub-block trenches 46 are in the upper portion of memory blocks 58 and are individually between immediately-laterally-adjacent sub-blocks 59 (i.e., there being no other sub-block between those that are immediately-laterally-adjacent one another) and individually extend through and horizontally-along select-gate tiers 22s and insulative tiers 20 of sub-blocks 59. For brevity, only two select-gate tiers 22s are shown and more likely there would be more than two select-gate tiers 22s (not shown).

Channel openings 25 have been formed (e.g., by etching) through insulative tiers 20 and conductive tiers 22* to conductor tier 16. Channel openings 25 may taper radially-inward (not shown) moving deeper in stack 18. In some embodiments, channel openings 25 may go into conductor material 17 of conductor tier 16 as shown or may stop there-atop (not shown). Alternately, as an example, channel openings 25 may stop atop or within the lowest insulative tier 20. A reason for extending channel openings 25 at least to conductor material 17 of conductor tier 16 is to assure direct electrical coupling of channel material to conductor tier 16 without using alternative processing and structure to do so when such a connection is desired. Etch-stop material (not shown) may be within or atop conductor material 17 of conductor tier 16 to facilitate stopping of the etching of channel openings 25 relative to conductor tier 16 when such is desired. Such etch-stop material may be sacrificial or non-sacrificial. By way of example and for brevity only, channel openings 25 are shown as being arranged in groups or columns of staggered rows of two openings 25 per row in sub-blocks 59. Any alternate existing or future-developed arrangement and construction may be used.

Example memory blocks 58 are shown as at least in part having been defined by horizontally-elongated trenches 40 that were formed (e.g., by anisotropic etching) into stack 18. Trenches 40 may have respective bottoms that are directly against conductor material 17 (e.g., atop or within) of conductor tier 16 (as shown) or may have respective bottoms that are above conductor material 17 of conductor tier 16 (not shown).

Transistor channel material may be formed in the individual channel openings elevationally along the insulative tiers and the conductive tiers, thus comprising individual channel-material strings, which is directly electrically coupled with conductive material in the conductor tier. Individual memory cells of the example memory array being formed may comprise a gate region (e.g., a control-gate region) and a memory structure laterally between the gate region and the channel material. In one such embodiment, the memory structure is formed to comprise a charge-blocking region, storage material (e.g., charge-storage material), and an insulative charge-passage material. The storage material (e.g., floating gate material such as doped or undoped silicon or charge-trapping material such as silicon nitride, metal dots, etc.) of the individual memory cells is elevationally along individual of the charge-blocking regions. The insulative charge-passage material (e.g., a band gap-engineered structure having nitrogen-containing material [e.g., silicon nitride] sandwiched between two insulator oxides [e.g., silicon dioxide]) is laterally between the channel material and the storage material.

FIGS. 1-6 show one embodiment wherein charge-blocking material 30, storage material 32, and charge-passage material 34 have been formed in individual channel openings 25 elevationally along insulative tiers 20 and conductive tiers 22*. Transistor materials 30, 32, and 34 (e.g., memory-cell materials) may be formed by, for example, deposition of respective thin layers thereof over stack 18 and within individual channel openings 25 followed by planarizing such back at least to a top surface of stack 18.

Channel material 36 has also been formed in channel openings 25 elevationally along insulative tiers 20 and conductive tiers 22* and comprises individual operative channel-material strings 53, in one embodiment having memory-cell materials (e.g., 30, 32, and 34) there-along and with material 24 in insulative tiers 20 being horizontally-between immediately-adjacent channel-material strings 53. Materials 30, 32, 34, and 36 are collectively shown as and only designated as material 37 in some figures due to scale. Example channel materials 36 include appropriately-doped crystalline semiconductor material, such as one or more silicon, germanium, and so-called III/V semiconductor materials (e.g., GaAs, InP, GaP, and GaN). Example thickness for each of materials 30, 32, 34, and 36 is 25 to 100 Angstroms. Punch etching may be conducted as shown to remove materials 30, 32, and 34 from the bases of channel openings 25 to expose conductor tier 16 such that channel material 36 is directly against conductor material 17 of conductor tier 16. Such punch etching may occur separately with respect to each of materials 30, 32, and 34 (as shown) or may occur collectively with respect to all after deposition of material 34 (not shown). Alternately, and by way of example only, no punch etching may be conducted and channel material 36 may be directly electrically coupled to conductor material 17 of conductor tier 16 by a separate conductive interconnect (not shown). Channel openings 25 are shown as comprising a radially-central solid dielectric material 38 (e.g., spin-on-dielectric, silicon dioxide, and/or silicon nitride). Alternately, and by way of example only, the radially-central portion within channel openings 25 may include void space(s) (not shown) and/or be devoid of solid material (not shown).

Example conductive tiers 22* comprise conducting material 48 that is part of individual conductive lines 29 (e.g., wordlines) that are also part of elevationally-extending strings 49 of individual transistors and/or memory cells 56. Conducting material 48 also comprises individual select gates 83 in individual select-gate tiers 22s. Two or more of select gates 83 may be directly electrically coupled, or otherwise electrically coupled, relative one another (not shown). A thin insulative liner (e.g., Al₂O₃ and not shown) may be formed before forming conducting material 48. Approximate locations of transistors and/or memory cells 56 are indicated with a bracket in some figures and some with dashed outlines in some figures, with transistors and/or memory cells 56 being essentially ring-like or annular in the depicted example. Alternately, transistors and/or memory cells 56 may not be completely encircling relative to individual channel openings 25 such that each channel opening 25 may have two or more elevationally-extending strings 49 (e.g., multiple transistors and/or memory cells about individual channel openings in individual conductive tiers with perhaps multiple wordlines per channel opening in individual conductive tiers, and not shown). Conducting material 48 may be considered as having terminal ends 50 corresponding to control-gate regions 52 of individual transistors and/or memory cells 56. Control-gate regions 52 in the depicted embodiment comprise individual portions of individual conductive lines 29. Materials 30, 32, and 34 may be considered as a memory structure 65 that is laterally between control-gate region 52 and channel material 36.

A charge-blocking region (e.g., charge-blocking material 30) is between storage material 32 and individual control-gate regions 52. A charge block may have the following functions in a memory cell: In a program mode, the charge block may prevent charge carriers from passing out of the storage material (e.g., floating-gate material, charge-trapping material, etc.) toward the control gate, and in an erase mode the charge block may prevent charge carriers from flowing into the storage material from the control gate. Accordingly, a charge block may function to block charge migration between the control-gate region and the storage material of individual memory cells. An example charge-blocking region as shown comprises insulator material 30. By way of further examples, a charge-blocking region may comprise a laterally (e.g., radially) outer portion of the storage material (e.g., material 32) where such storage material is insulative (e.g., in the absence of any different-composition material between an insulative storage material 32 and conducting material 48). Regardless, as an additional example, an interface of a storage material and conductive material of a control gate may be sufficient to function as a charge-blocking region in the absence of any separate-composition-insulator material 30. Further, an interface of conducting material 48 with material 30 (when present) in combination with insulator material 30 may together function as a charge-blocking region, and as alternately or additionally may a laterally-outer region of an insulative storage material (e.g., a silicon nitride material 32). An example material 30 is one or more of silicon hafnium oxide and silicon dioxide.

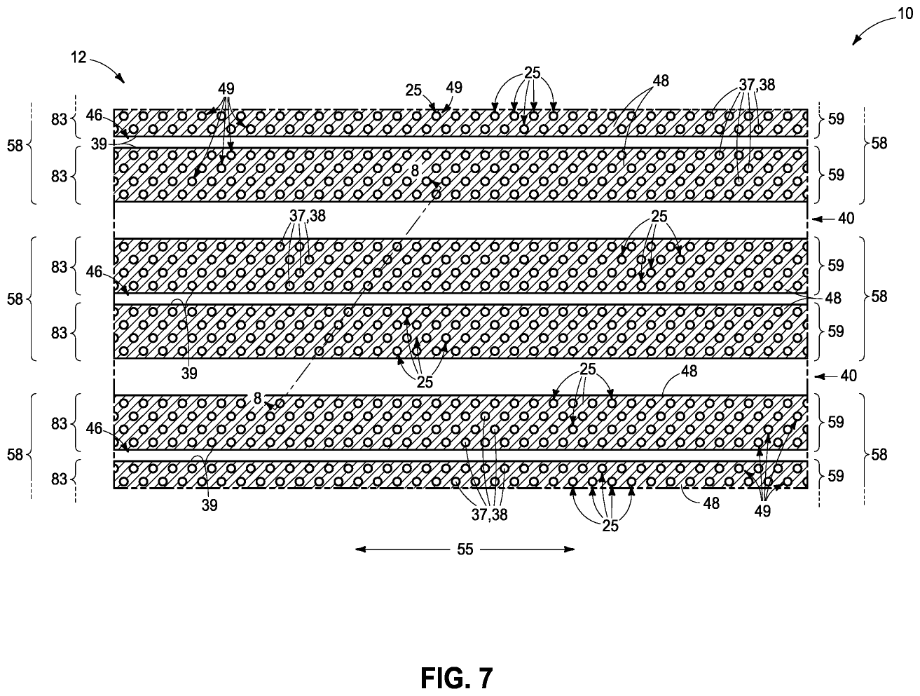

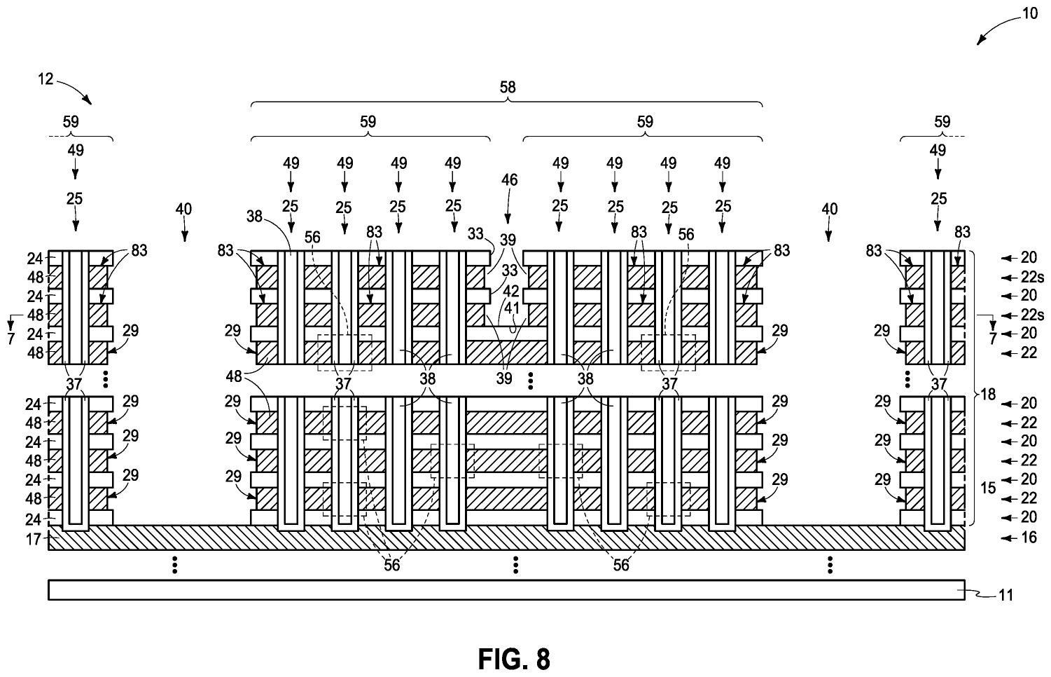

Referring to FIGS. 7 and 8, conducting material 48 of select-gate tiers 22s has been recessed (e.g., by etching) in sub-block trenches 46 laterally-outward relative to sub-block trench sidewalls 33 of insulative material 24 of insulative tiers 20 of sub-blocks 59 to form lateral recesses 39 in select-gate tiers 22s. Recesses may also be formed relative to trenches 40 as shown (not numerically designated).

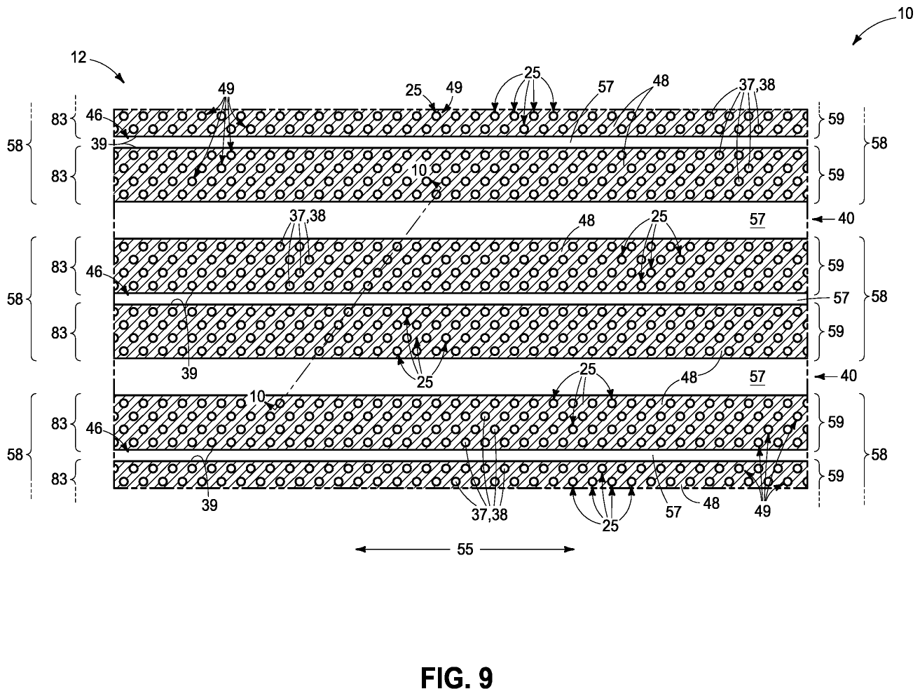

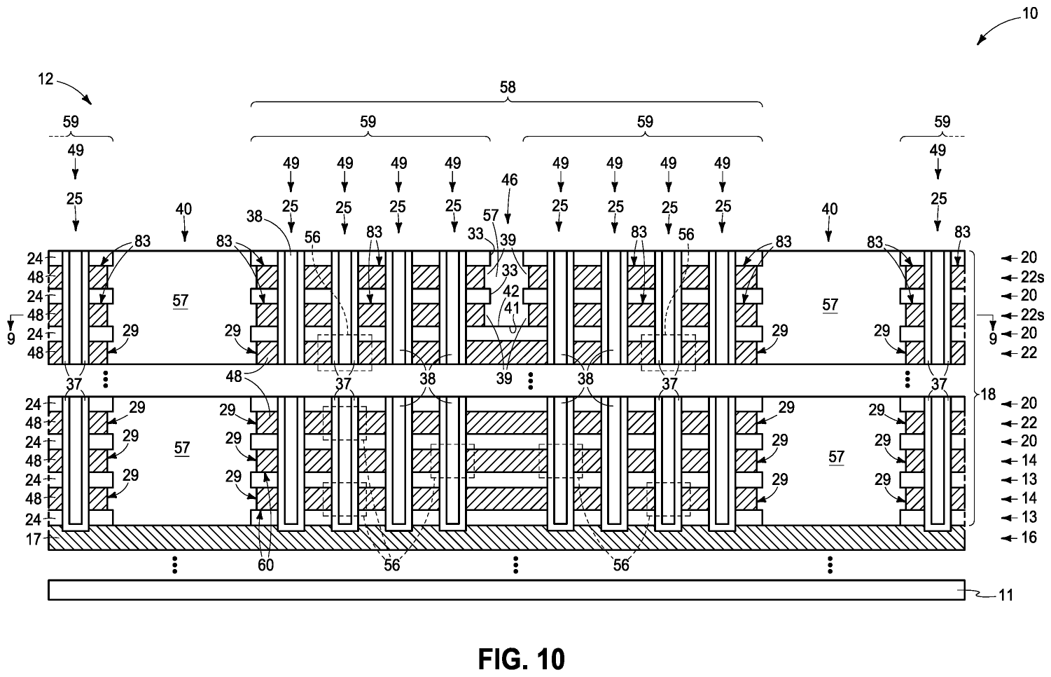

Referring to FIGS. 9 and 10, insulating material 57 (e.g., silicon dioxide, silicon nitride, and/or aluminum oxide) has been formed in sub-block trenches 46, in lateral recesses 39 therein, and in trenches 40. Such provides lateral electrical isolation (insulation) between immediately-laterally-adjacent memory blocks 58 and between immediately-laterally-adjacent sub-blocks 59. Insulating material 57 may include through-array-vias (TAVs, not shown). Insulating material 57 may be formed in trenches 46 and 40 at the same or different time(s) and if at different times may be of the same or different composition(s) in trenches 46 compared to trenches 40.f

Any other attribute(s) or aspect(s) as shown and/or described herein with respect to other embodiments may be used in the embodiments shown and described with reference to the above embodiments.

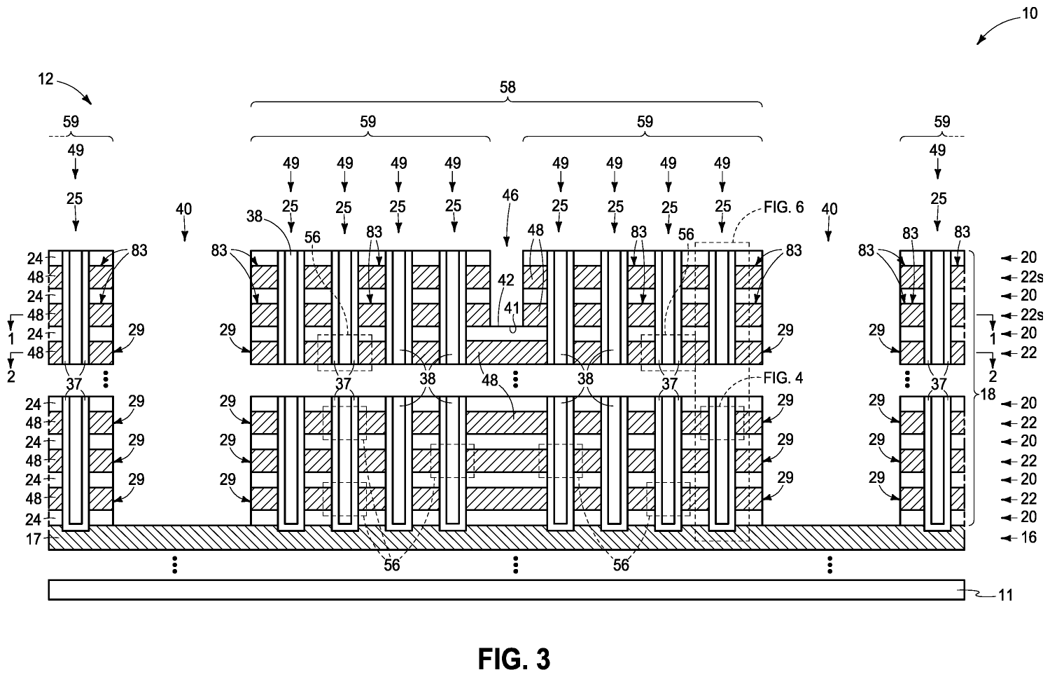

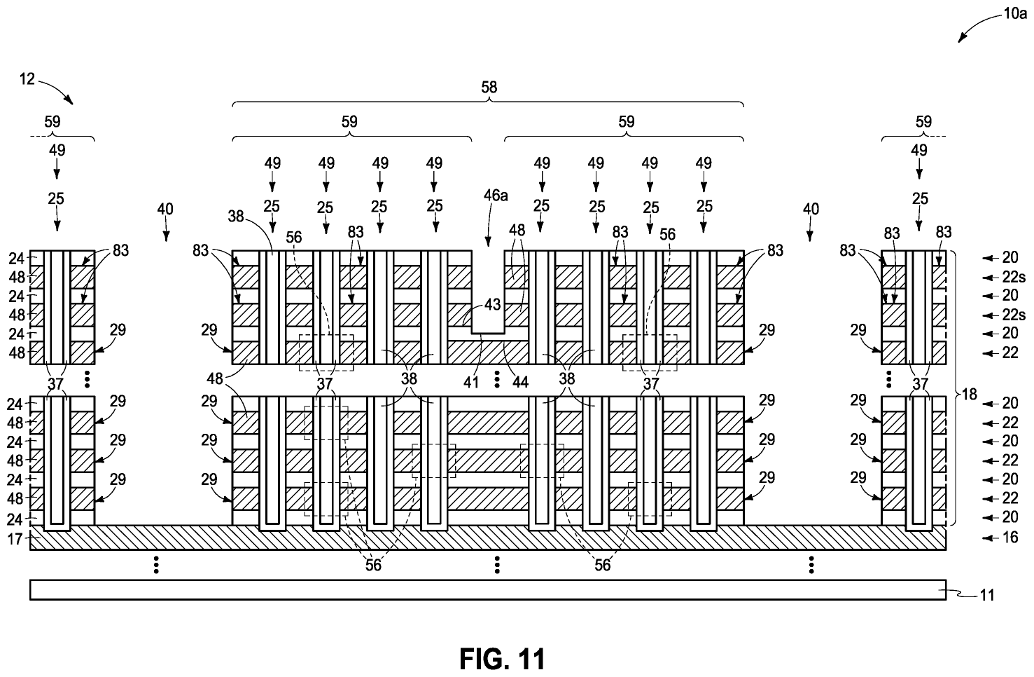

FIG. 3 shows an example embodiment where sub-block trenches 46 individually have a bottom 41 that is at a top 42 of the insulative tier 20 that is immediately-directly-below a lowest of select-gate tiers 22s that is in the upper portion of memory blocks 58 (i.e., there being no other insulative tier 20 between such lowest select-gate tier and that which is immediately-directly-therebelow). FIG. 11 shows an alternate-embodiment construction 10a where sub-block trenches 46a individually have a bottom 41 that is between a top 43 and a bottom 44 of the insulative tier 20 that is immediately-directly-below the lowest select-gate tier 22s that is in the upper portion of memory blocks 58. Like numerals from the above-described embodiments have been used where appropriate, with some construction differences being indicated with the suffix “a” or with different numerals. Any other attribute(s) or aspect(s) as shown and/or described herein with respect to other embodiments may be used.

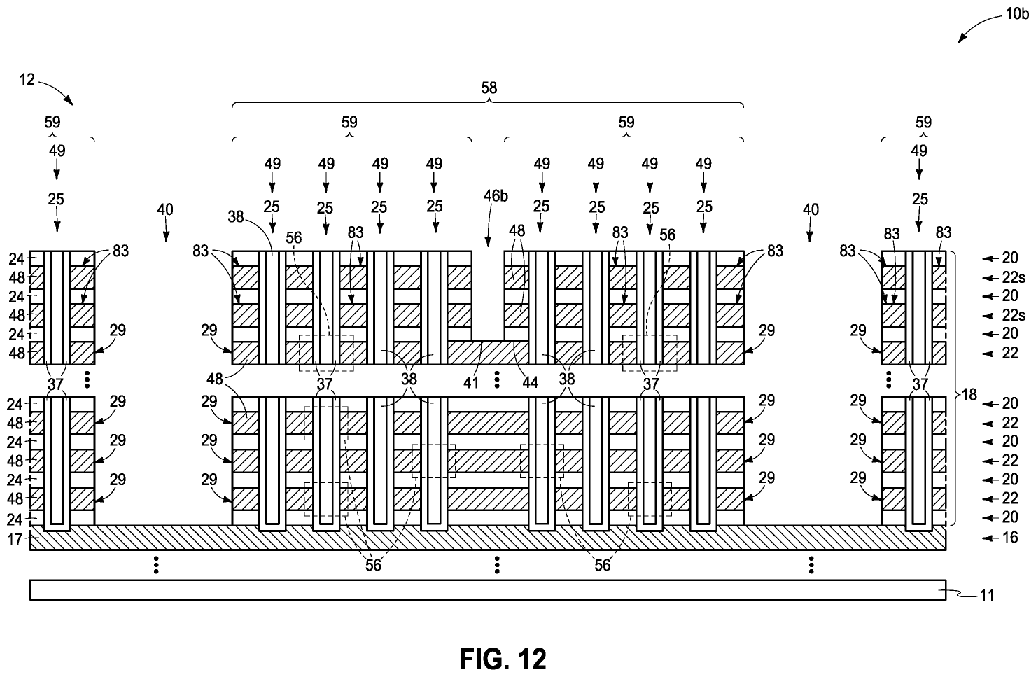

FIG. 12 shows an alternate-embodiment construction 10b (corresponding to that of FIGS. 3 and 11) where sub-block trenches 46b individually have a bottom 41 that is at bottom 44 of the insulative tier 20 that is immediately-directly-below the lowest of select-gate tiers 22s that is in the upper portion of memory blocks 58 (e.g., forming the sub-block trenches to extend downwardly to the conductive tier [at least thereto] that is immediately-directly-below a lowest of the select-gate tiers that is in the upper portion of the memory blocks). Like numerals from the above-described embodiments have been used where appropriate, with some construction differences being indicated with the suffix “b” or with different numerals. Any other attribute(s) or aspect(s) as shown and/or described herein with respect to other embodiments may be used.

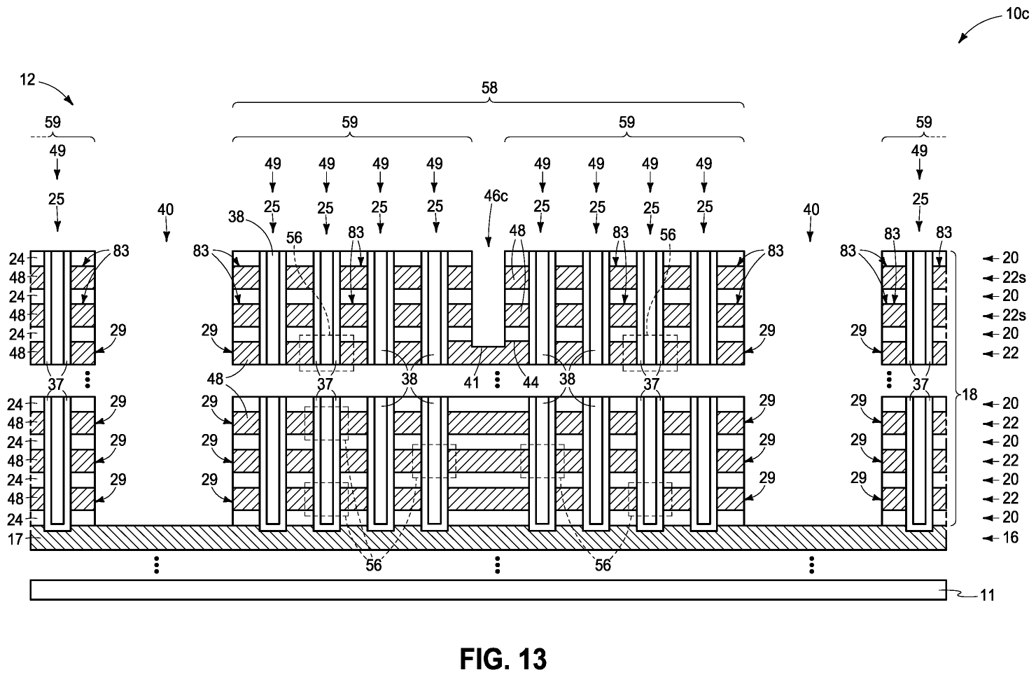

FIG. 13 shows an alternate-embodiment construction 10c (corresponding to that of FIGS. 3, 11, and 12) where sub-block trenches 46c have been formed to extend downwardly into the conductive tier 22 that is immediately-directly-below the lowest select-gate tier 22s in the upper portion of memory block 58. Like numerals from the above-described embodiments have been used where appropriate, with some construction differences being indicated with the suffix “c” or with different numerals. Any other attribute(s) or aspect(s) as shown and/or described herein with respect to other embodiments may be used.

In embodiments where sub-block trenches 46* are formed to extend downwardly at least to conductive tier 22 that is immediately-directly-below lowest select-gate tier 22s that is in the upper portion of memory blocks 58, the act of recessing will also likely remove some of conducting material 48 that is in conductive tier 22 that is immediately-directly-below said lowest select-gate tier 22s. Further, in some such embodiments, the act of recessing also recesses conducting material 48 of conductive tier 22 that is immediately-directly-below said lowest select-gate tier 22s laterally-outward relative to sub-block trench sidewalls of insulative material 24 of the insulative tier 20 that is immediately-directly-below said lowest select-gate tier 22s to form lateral recesses in the conductive tier 22 that is immediately-directly-below said lowest select-gate tier 22s.

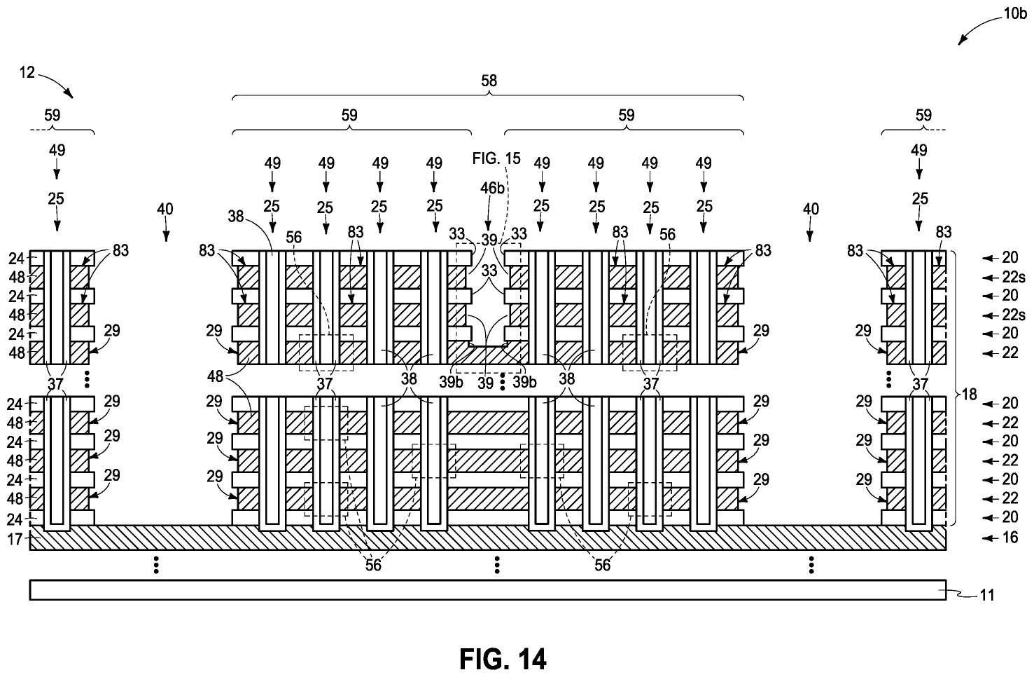

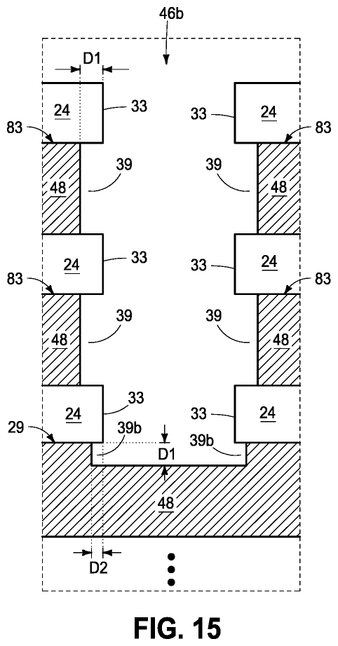

For example, FIGS. 14 and 15 show example processing after that shown by FIG. 12 with respect to construction 10b whereby lateral recesses 39b have also been formed in conductive tier 22 that is immediately-directly-below said lowest select-gate tier 22s. Example lateral recesses 39b have lateral depth D1 (i.e., on average if not constant) relative to sub-block trench sidewalls 33 of insulative material 24 of the insulative tier 20 that is immediately-directly-below said lowest select-gate tier 22s that is less than lateral depth D2 of lateral recesses 39. Such may occur, for example the depicted tapered profile of lateral recess 39b, due to greater time of lateral etching of conducting material 48 towards the top thereof vs. the bottom thereof. Any other attribute(s) or aspect(s) as shown and/or described herein with respect to other embodiments may be used.

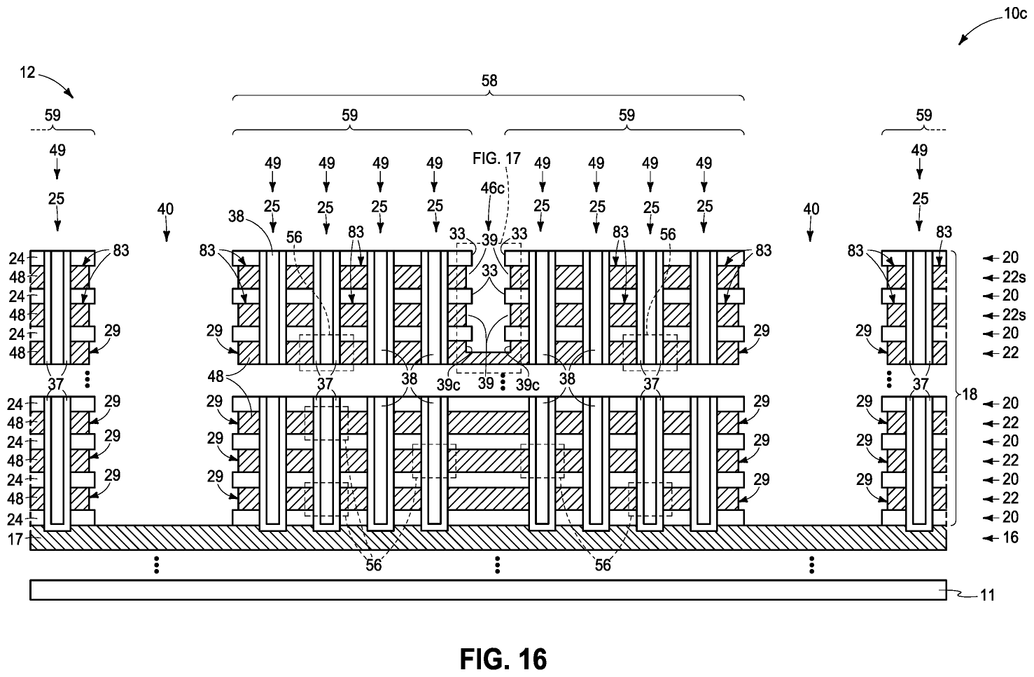

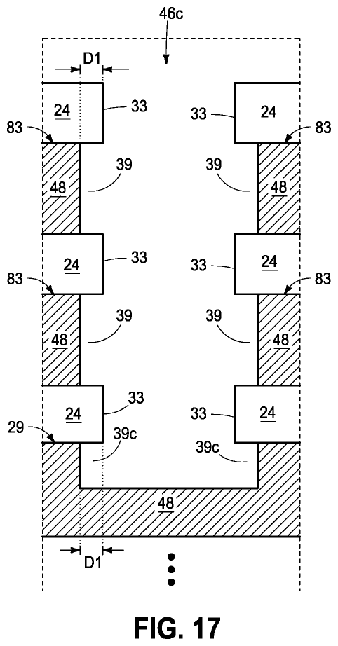

FIGS. 16 and 17 shows example processing after that shown by FIG. 13 with respect to construction 10c whereby lateral recesses 39c have also been formed in conductive tier 22 that is immediately-directly-below said lowest select-gate tier 22s. Example lateral recesses 39c have lateral depth D1 (i.e., on average if not constant) relative to sub-block trench sidewalls 33 of insulative material 24 of the insulative tier 20 that is immediately-directly-below said lowest select-gate tier 22s that is the same as lateral depth D1 of lateral recesses 39. Such may occur, for example the depicted non-tapered profile of lateral recess 39c, due to same time of lateral etching of conducting material 48 at the top and bottom thereof. Any other attribute(s) or aspect(s) as shown and/or described herein with respect to other embodiments may be used.

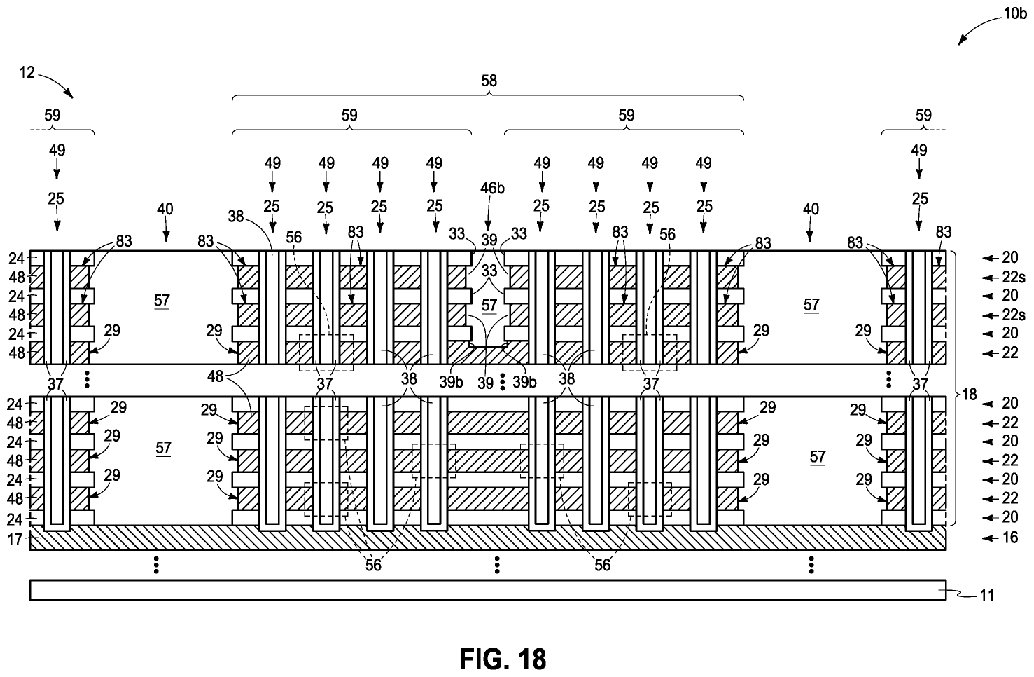

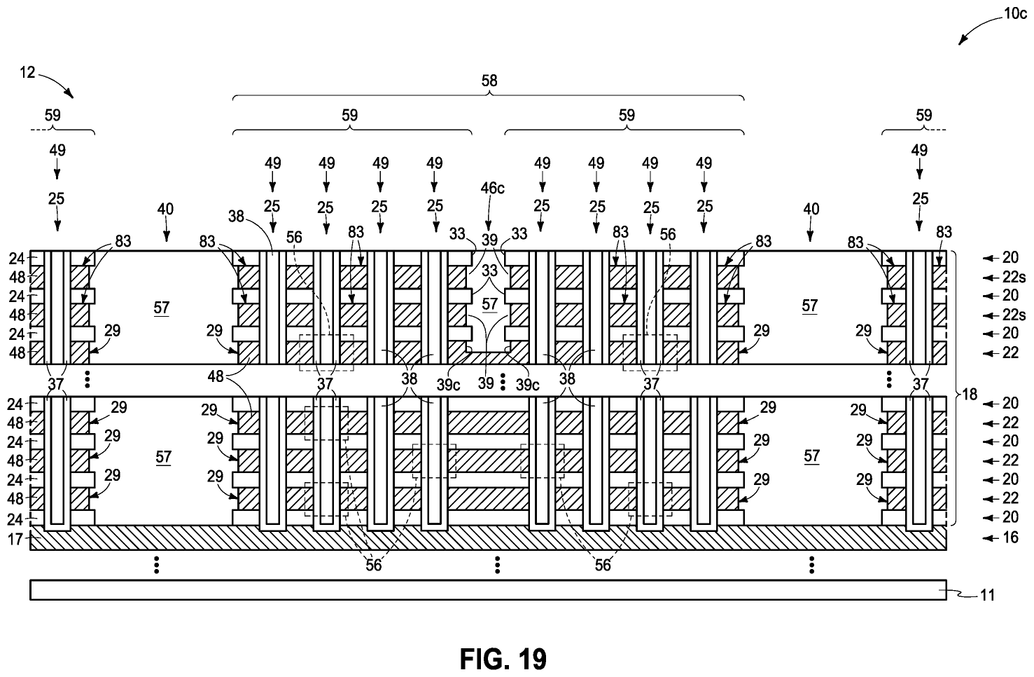

FIGS. 18 and 19 show example subsequent processing to that of FIGS. 14 and 16, respectively, wherein insulating material 57 has been formed in trenches 46* and 57.

Forming recesses 39* may reduce or prevent left-over chemicals or residues that could result in electrical shorting or downstream metal (48) interaction and loss. Forming recesses 39* may also remove metal (48) that was damaged during dry etch, strip, and/or clean, thereby preventing or reducing possible blowout or void formation.

Alternate embodiment constructions may result from method embodiments described above, or otherwise. Regardless, embodiments of the invention encompass memory arrays independent of method of manufacture. Nevertheless, such memory arrays may have any of the attributes as described herein in method embodiments. Likewise, the above-described method embodiments may incorporate, form, and/or have any of the attributes described with respect to device embodiments.

In one embodiment, a memory array (e.g., 12) comprising strings (e.g., 49) of memory cells (e.g., 56) comprises a stack (e.g., 18) comprising vertically-alternating insulative tiers (e.g., 20) and conductive tiers (e.g., 22*). The stack comprises laterally-spaced memory blocks (e.g., 58) an upper portion of which individually comprise sub-blocks (e.g., 59). The conductive tiers of the sub-blocks individually comprise select-gate tiers (e.g., 22s) that individually comprise select gates (e.g., 83). Strings (e.g., 49) of memory cells (e.g., 56) comprising channel-material strings (e.g., 53) extend through the insulative tiers and the conductive tiers in the memory blocks and sub-blocks. Sub-block trenches (e.g., 46*) are in the upper portion of the memory blocks and are individually between immediately-laterally-adjacent of the sub-blocks. The sub-block trenches individually extend through and horizontally-along the select-gate tiers and the insulative tiers of the sub-blocks. The select-gate tiers in the sub-block trenches comprise lateral recesses (e.g., 39) that are laterally-outward of sub-block trench sidewalls (e.g., 33) of insulative material (e.g., 24) of the insulative tiers of the sub-blocks. Insulating material (e.g., 57) is in the sub-block trenches and in the lateral recesses. Any other attribute(s) or aspect(s) as shown and/or described herein with respect to other embodiments may be used.

In one embodiment, a memory array (e.g., 12) comprising strings (e.g., 49) of memory cells (e.g., 56) comprises a stack (e.g., 18) comprising vertically-alternating insulative tiers (e.g., 20) and conductive tiers (e.g., 22*). The stack comprises laterally-spaced memory blocks (e.g., 58) an upper portion of which individually comprise sub-blocks (e.g., 59). The conductive tiers of the sub-blocks individually comprise select-gate tiers (e.g., 22s) that individually comprise select gates (e.g., 83). Strings (e.g., 49) of memory cells (e.g., 56) comprising channel-material strings (e.g., 53) extend through the insulative tiers and the conductive tiers in the memory blocks and sub-blocks. Sub-block trenches (e.g., 46*) are in the upper portion of the memory blocks and are individually between immediately-laterally-adjacent of the sub-blocks. The sub-block trenches extend downwardly into the conductive tier that is immediately-directly-below a lowest of the select-gate tiers that is in the upper portion of the memory blocks. The select-gate tiers in the sub-block trenches comprise lateral recesses (e.g., 39) that are laterally-outward of sub-block trench sidewalls (e.g., 33) of insulative material (e.g., 24) of the insulative tiers of the sub-blocks. Insulating material (e.g., 57) is in the sub-block trenches, with the insulating material extending into the lateral recesses and downwardly into the conductive tier that is immediately-directly-below said lowest select-gate tier. Any other attribute(s) or aspect(s) as shown and/or described herein with respect to other embodiments may be used.

The above processing(s) or construction(s) may be considered as being relative to an array of components formed as or within a single stack or single deck of such components above or as part of an underlying base substrate (albeit, the single stack/deck may have multiple tiers). Control and/or other peripheral circuitry for operating or accessing such components within an array may also be formed anywhere as part of the finished construction, and in some embodiments may be under the array (e.g., CMOS under-array). Regardless, one or more additional such stack(s)/deck(s) may be provided or fabricated above and/or below that shown in the figures or described above. Further, the array(s) of components may be the same or different relative one another in different stacks/decks and different stacks/decks may be of the same thickness or of different thicknesses relative one another. Intervening structure may be provided between immediately-vertically-adjacent stacks/decks (e.g., additional circuitry and/or dielectric layers). Also, different stacks/decks may be electrically coupled relative one another. The multiple stacks/decks may be fabricated separately and sequentially (e.g., one atop another), or two or more stacks/decks may be fabricated at essentially the same time.

The assemblies and structures discussed above may be used in integrated circuits/circuitry and may be incorporated into electronic systems. Such electronic systems may be used in, for example, memory modules, device drivers, power modules, communication modems, processor modules, and application-specific modules, and may include multilayer, multichip modules. The electronic systems may be any of a broad range of systems, such as, for example, cameras, wireless devices, displays, chip sets, set top boxes, games, lighting, vehicles, clocks, televisions, cell phones, personal computers, automobiles, industrial control systems, aircraft, etc.

In this document unless otherwise indicated, “elevational”, “higher”, “upper”, “lower”, “top”, “atop”, “bottom”, “above”, “below”, “under”, “beneath”, “up”, and “down” are generally with reference to the vertical direction. “Horizontal” refers to a general direction (i.e., within 10 degrees) along a primary substrate surface and may be relative to which the substrate is processed during fabrication, and vertical is a direction generally orthogonal thereto. Reference to “exactly horizontal” is the direction along the primary substrate surface (i.e., no degrees there-from) and may be relative to which the substrate is processed during fabrication. Further, “vertical” and “horizontal” as used herein are generally perpendicular directions relative one another and independent of orientation of the substrate in three-dimensional space. Additionally, “elevationally-extending” and “extend(ing) elevationally” refer to a direction that is angled away by at least 45° from exactly horizontal. Further, “extend(ing) elevationally”, “elevationally-extending”, “extend(ing) horizontally”, “horizontally-extending” and the like with respect to a field effect transistor are with reference to orientation of the transistor's channel length along which current flows in operation between the source/drain regions. For bipolar junction transistors, “extend(ing) elevationally” “elevationally-extending”, “extend(ing) horizontally”, “horizontally-extending” and the like, are with reference to orientation of the base length along which current flows in operation between the emitter and collector. In some embodiments, any component, feature, and/or region that extends elevationally extends vertically or within 10° of vertical.

Further, “directly above”, “directly below”, and “directly under” require at least some lateral overlap (i.e., horizontally) of two stated regions/materials/components relative one another. Also, use of “above” not preceded by “directly” only requires that some portion of the stated region/material/component that is above the other be elevationally outward of the other (i.e., independent of whether there is any lateral overlap of the two stated regions/materials/components). Analogously, use of “below” and “under” not preceded by “directly” only requires that some portion of the stated region/material/component that is below/under the other be elevationally inward of the other (i.e., independent of whether there is any lateral overlap of the two stated regions/materials/components).

Any of the materials, regions, and structures described herein may be homogenous or non-homogenous, and regardless may be continuous or discontinuous over any material which such overlie. Where one or more example composition(s) is/are provided for any material, that material may comprise, consist essentially of, or consist of such one or more composition(s). Further, unless otherwise stated, each material may be formed using any suitable existing or future-developed technique, with atomic layer deposition, chemical vapor deposition, physical vapor deposition, epitaxial growth, diffusion doping, and ion implanting being examples.

Additionally, “thickness” by itself (no preceding directional adjective) is defined as the mean straight-line distance through a given material or region perpendicularly from a closest surface of an immediately-adjacent material of different composition or of an immediately-adjacent region. Additionally, the various materials or regions described herein may be of substantially constant thickness or of variable thicknesses. If of variable thickness, thickness refers to average thickness unless otherwise indicated, and such material or region will have some minimum thickness and some maximum thickness due to the thickness being variable. As used herein, “different composition” only requires those portions of two stated materials or regions that may be directly against one another to be chemically and/or physically different, for example if such materials or regions are not homogenous. If the two stated materials or regions are not directly against one another, “different composition” only requires that those portions of the two stated materials or regions that are closest to one another be chemically and/or physically different if such materials or regions are not homogenous. In this document, a material, region, or structure is “directly against” another when there is at least some physical touching contact of the stated materials, regions, or structures relative one another. In contrast, “over”, “on”, “adjacent”, “along”, and “against” not preceded by “directly” encompass “directly against” as well as construction where intervening material(s), region(s), or structure(s) result(s) in no physical touching contact of the stated materials, regions, or structures relative one another.

Herein, regions-materials-components are “electrically coupled” relative one another if in normal operation electric current is capable of continuously flowing from one to the other and does so predominately by movement of subatomic positive and/or negative charges when such are sufficiently generated. Another electronic component may be between and electrically coupled to the regions-materials-components. In contrast, when regions-materials-components are referred to as being “directly electrically coupled”, no intervening electronic component (e.g., no diode, transistor, resistor, transducer, switch, fuse, etc.) is between the directly electrically coupled regions-materials-components.

Any use of “row” and “column” in this document is for convenience in distinguishing one series or orientation of features from another series or orientation of features and along which components have been or may be formed. “Row” and “column” are used synonymously with respect to any series of regions, components, and/or features independent of function. Regardless, the rows may be straight and/or curved and/or parallel and/or not parallel relative one another, as may be the columns. Further, the rows and columns may intersect relative one another at 90° or at one or more other angles (i.e., other than the straight angle).

The composition of any of the conductive/conductor/conducting materials herein may be conductive metal material and/or conductively-doped semiconductive/semiconductor/semiconducting material. “Metal material” is any one or combination of an elemental metal, any mixture or alloy of two or more elemental metals, and any one or more metallic compound(s).

Herein, any use of “selective” as to etch, etching, removing, removal, depositing, forming, and/or formation is such an act of one stated material relative to another stated material(s) so acted upon at a rate of at least 2:1 by volume. Further, any use of selectively depositing, selectively growing, or selectively forming is depositing, growing, or forming one material relative to another stated material or materials at a rate of at least 2:1 by volume for at least the first 75 Angstroms of depositing, growing, or forming.

Unless otherwise indicated, use of “or” herein encompasses either and both.

### CONCLUSION

In some embodiments, a method used in forming a memory array comprising strings of memory cells comprises forming a stack comprising vertically-alternating insulative tiers and conductive tiers. The stack comprises laterally-spaced memory blocks an upper portion of which individually comprise sub-blocks. The conductive tiers of the sub-blocks individually comprise select-gate tiers that individually comprise select gates. Sub-block trenches are in the upper portion of the memory blocks and are individually between immediately-laterally-adjacent of the sub-blocks. The sub-block trenches individually extend through and horizontally-along the select-gate tiers and the insulative tiers of the sub-blocks. In the sub-block trenches, conducting material of the select-gate tiers is recessed laterally-outward relative to sub-block trench sidewalls of insulative material of the insulative tiers of the sub-blocks to form lateral recesses in the select-gate tiers. Insulating material is formed in the sub-block trenches and in the lateral recesses.

In some embodiments, a memory array comprising strings of memory cells comprises a stack comprising vertically-alternating insulative tiers and conductive tiers. The stack comprises laterally-spaced memory blocks an upper portion of which individually comprise sub-blocks. The conductive tiers of the sub-blocks individually comprise select-gate tiers that individually comprise select gates. Strings of memory cells comprise channel-material strings that extend through the insulative tiers and the conductive tiers in the memory blocks and sub-blocks. Sub-block trenches are in the upper portion of the memory blocks that are individually between immediately-laterally-adjacent of the sub-blocks. The sub-block trenches individually extend through and horizontally-along the select-gate tiers and the insulative tiers of the sub-blocks. The select-gate tiers in the sub-block trenches comprise lateral recesses that are laterally-outward of sub-block trench sidewalls of insulative material of the insulative tiers of the sub-blocks. Insulating material is in the sub-block trenches and in the lateral recesses.

In some embodiments, a memory array comprising strings of memory cells comprises a stack comprising vertically-alternating insulative tiers and conductive tiers. The stack comprises laterally-spaced memory blocks an upper portion of which individually comprise sub-blocks. The conductive tiers of the sub-blocks individually comprise select-gate tiers that individually comprise select gates. Strings of memory cells comprise channel-material strings that extend through the insulative tiers and the conductive tiers in the memory blocks and sub-blocks. Sub-block trenches are in the upper portion of the memory blocks and are individually between immediately-laterally-adjacent of the sub-blocks. The sub-block trenches individually extend through and horizontally-along the select-gate tiers and the insulative tiers of the sub-blocks. The sub-block trenches extend downwardly into the conductive tier that is immediately-directly-below a lowest of the select-gate tiers that is in the upper portion of the memory blocks. The select-gate tiers in the sub-block trenches comprise lateral recesses that are laterally-outward of sub-block trench sidewalls of insulative material of the insulative tiers of the sub-blocks. Insulating material is in the sub-block trenches. The insulating material in the sub-block trenches extends into the lateral recesses and downwardly into the conductive tier that is immediately-directly-below said lowest select-gate tier.

In compliance with the statute, the subject matter disclosed herein has been described in language more or less specific as to structural and methodical features. It is to be understood, however, that the claims are not limited to the specific features shown and described, since the means herein disclosed comprise example embodiments. The claims are thus to be afforded full scope as literally worded, and to be appropriately interpreted in accordance with the doctrine of equivalents.

1. A method used in forming a memory array comprising strings of memory cells, comprising:
forming a stack comprising vertically-alternating insulative tiers and conductive tiers, the stack comprising laterally-spaced memory blocks an upper portion of which individually comprise sub-blocks, the conductive tiers of the sub-blocks individually comprising select-gate tiers that individually comprise select gates, sub-block trenches in the upper portion of the memory blocks that are individually between immediately-laterally-adjacent of the sub-blocks, the sub-block trenches individually extending through and horizontally-along the select-gate tiers and the insulative tiers of the sub-blocks;
in the sub-block trenches, recessing conducting material of the select-gate tiers laterally-outward relative to sub-block trench sidewalls of insulative material of the insulative tiers of the sub-blocks to form lateral recesses in the select-gate tiers; and
forming insulating material in the sub-block trenches and in the lateral recesses.

2. The method of claim 1 wherein the recessing comprises etching.

3. The method of claim 1 wherein the sub-block trenches individually have a bottom that is at a top of the insulative tier that is immediately-directly-below a lowest of the select-gate tiers that is in the upper portion of the memory blocks.

4. The method of claim 1 wherein the sub-block trenches individually have a bottom that is between a top and a bottom of the insulative tier that is immediately-directly-below a lowest of the select-gate tiers that is in the upper portion of the memory blocks.

5. The method of claim 1 wherein the sub-block trenches individually have a bottom that is at a bottom of the insulative tier that is immediately-directly-below a lowest of the select-gate tiers that is in the upper portion of the memory blocks.

6. The method of claim 1 comprising forming the sub-block trenches to extend downwardly to the conductive tier that is immediately-directly-below a lowest of the select-gate tiers that is in the upper portion of the memory blocks.

7. The method of claim 6 wherein the recessing also removes some of the conducting material that is in the conductive tier that is immediately-directly-below said lowest select-gate tier.

8. The method of claim 7 wherein the recessing also recesses the conducting material of the conductive tier that is immediately-directly-below said lowest select-gate tier laterally-outward relative to sub-block trench sidewalls of the insulative material of the insulative tier that is immediately-directly-below said lowest select-gate tier to form lateral recesses in the conductive tier that is immediately-directly-below said lowest select-gate tier.

9. The method of claim 8 wherein the lateral recesses in the conductive tier that is immediately-directly-below said lowest select-gate tier have less lateral depth relative to the sub-block trench sidewalls of the insulative material of the insulative tier that is immediately-directly-below said lowest select-gate tier than lateral depth of the lateral recesses in the select-gate tiers relative to the sub-block trench sidewalls of the insulative material of the insulative tiers of the sub-blocks.

10. The method of claim 8,
comprising forming the sub-block trenches to extend downwardly into the conductive tier that is immediately-directly-below said lowest select-gate tier; and
wherein the lateral recesses in the conductive tier that is immediately-directly-below said lowest select-gate tier have the same lateral depth relative to the sub-block trench sidewalls of the insulative material of the insulative tier that is immediately-directly-below said lowest select-gate tier as lateral depth of the lateral recesses in the select-gate tiers relative to the sub-block trench sidewalls of the insulative material of the insulative tiers of the sub-blocks.

11. A memory array comprising strings of memory cells, comprising:
a stack comprising vertically-alternating insulative tiers and conductive tiers, the stack comprising laterally-spaced memory blocks an upper portion of which individually comprise sub-blocks, the conductive tiers of the sub-blocks individually comprising select-gate tiers that individually comprise select gates, strings of memory cells comprising channel-material strings that extend through the insulative tiers and the conductive tiers in the memory blocks and sub-blocks;
sub-block trenches in the upper portion of the memory blocks that are individually between immediately-laterally-adjacent of the sub-blocks, the sub-block trenches individually extending through and horizontally-along the select-gate tiers and the insulative tiers of the sub-blocks;
the select-gate tiers in the sub-block trenches comprising lateral recesses that are laterally-outward of sub-block trench sidewalls of insulative material of the insulative tiers of the sub-blocks; and
insulating material in the sub-block trenches and in the lateral recesses.

12. The memory array of claim 11 wherein the sub-block trenches individually have a bottom that is at a top of the insulative tier that is immediately-directly-below a lowest of the select-gate tiers that is in the upper portion of the memory blocks.

13. The memory array of claim 11 wherein the sub-block trenches individually have a bottom that is between a top and a bottom of the insulative tier that is immediately-directly-below a lowest of the select-gate tiers that is in the upper portion of the memory blocks.

14. The memory array of claim 11 wherein the sub-block trenches individually have a bottom that is at a bottom of the insulative tier that is immediately-directly-below a lowest of the select-gate tiers that is in the upper portion of the memory blocks.

15. The memory array of claim 11 wherein the memory array comprises NAND.

16. A memory array comprising strings of memory cells, comprising:
a stack comprising vertically-alternating insulative tiers and conductive tiers, the stack comprising laterally-spaced memory blocks an upper portion of which individually comprise sub-blocks, the conductive tiers of the sub-blocks individually comprising select-gate tiers that individually comprise select gates, strings of memory cells comprising channel-material strings that extend through the insulative tiers and the conductive tiers in the memory blocks and sub-blocks;
sub-block trenches in the upper portion of the memory blocks that are individually between immediately-laterally-adjacent of the sub-blocks, the sub-block trenches individually extending through and horizontally-along the select-gate tiers and the insulative tiers of the sub-blocks, the sub-block trenches extending downwardly into the conductive tier that is immediately-directly-below a lowest of the select-gate tiers that is in the upper portion of the memory blocks;
the select-gate tiers in the sub-block trenches comprising lateral recesses that are laterally-outward of sub-block trench sidewalls of insulative material of the insulative tiers of the sub-blocks; and
insulating material in the sub-block trenches, the insulating material in the sub-block trenches extending into the lateral recesses and downwardly into the conductive tier that is immediately-directly-below said lowest select-gate tier.

17. The memory array of claim 16 wherein the conductive tier that is immediately-directly-below said lowest select-gate tier comprises lateral recesses relative to sub-block trench sidewalls of the insulative material of the insulative tier that is immediately-directly-below said lowest select-gate tier.

18. The memory array of claim 17 wherein the lateral recesses in the conductive tier that is immediately-directly-below said lowest select-gate tier have less lateral depth relative to the sub-block trench sidewalls of the insulative material of the insulative tier that is immediately-directly-below said lowest select-gate tier than lateral depth of the lateral recesses in the select-gate tiers relative to the sub-block trench sidewalls of the insulative material of the insulative tiers of the sub-blocks.

19. The memory array of claim 17 wherein the lateral recesses in the conductive tier that is immediately-directly-below said lowest select-gate tier have the same lateral depth relative to the sub-block trench sidewalls of the insulative material of the insulative tier that is immediately-directly-below said lowest select-gate tier as lateral depth of the lateral recesses in the select-gate tiers relative to the sub-block trench sidewalls of the insulative material of the insulative tiers of the sub-blocks.

20. The memory array of claim 16 wherein the memory array comprises NAND.
